(19) United States
(12) Patent Application Publication
(10) Pub. No.: US 2008/0080149 A1
(43) Pub. Date: Apr. 3, 2008

(54) Tray mechanism for servers

(76) Inventors: Timothy G. Hanna, Columbia, SC (US); Brandy G. Walters, Lexington, SC (US)

Correspondence Address: BUCKLEY, MASCHOFF & TALWALKAR LLC, 50 LOCUST AVENUE, NEW CANAAN, CT, 06840, US

(21) Appl. No.: 11/540,839

(22) Filed: Sep. 29, 2006

(51) Int. Cl. H05K 5/00

(52) U.S. Cl. 361/752

(57) ABSTRACT

According to some embodiments, an apparatus may comprise a printed circuit board, a second printed circuit board, a chassis, and a tray. The chassis may be coupled to the printed circuit board and may comprise a chassis base, a first side portion, and a second side portion. The tray may be coupled to the chassis and comprise a tray base having a first face and a second face, a first projection, and a second projection. The first projection may be substantially perpendicular to the first face, and the second projection may be substantially perpendicular to the first face. The second printed circuit board may be coupled to the second face of the tray base.

### BACKGROUND

Computer devices including servers, desktop computers, and laptops may comprise a plurality of electronic components (e.g. motherboards, memory modules, disk drives). The electronic components of a computer device may be stored in a housing to protect against water, static, dust, etc.

As more computing power is needed and electronic components become smaller, it may be convenient to group multiple housings together. Such grouping may conserve space but may hinder access to individual housings.

### BRIEF DESCRIPTION OF THE DRAWINGS

FIG. 1 is a front view of an apparatus according to some embodiments.

FIG. 2 is a front view of an apparatus according to some embodiments.

FIG. 3 is a front view of an apparatus according to some embodiments.

FIG. 4 is a flow diagram of a process according to some embodiments.

FIG. 5 is a perspective view of a system according to some embodiments.

FIG. 6 is a perspective view of a system according to some embodiments.

FIG. 7 is a perspective view of a system according to some embodiments.

FIG. 8 is an exploded view of an apparatus according to some embodiments.

### DETAILED DESCRIPTION

The several embodiments described herein are provided solely for the purpose of illustration. Embodiments may include any currently or hereafter-known versions of the elements described herein. Therefore, persons in the art will recognize from this description that other embodiments may be practiced with various modifications and alterations.

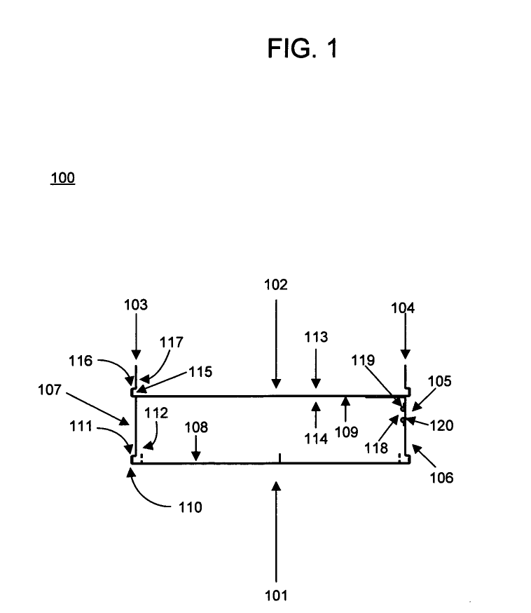

Now referring to FIG. 1, an embodiment of an apparatus 100 is shown. Apparatus 100 may comprise a chassis 101 coupled to a tray 102 and in some embodiments may be, but is not limited to, a housing for a computer, a rack mounted server, a blade server, or a laptop.

The chassis 101 may comprise a first side portion 106, a second side portion 107, and a chassis base 108. In some embodiments, the first side portion 106 and the second side portion 107 may each comprise a first part 110 coupled to the chassis base 108 and perpendicular to the chassis base 108, a second part 111 coupled to the first part and parallel to the chassis base 108, and a third part 112 coupled to the second part and perpendicular to the chassis base 108. In some embodiments, elements 110, 111, and 112 may be used as rails for enabling guided insertion/extraction into an enclosure or second chassis, or for mechanically strengthening of the chassis 101.

The tray 102 may comprise a tray base 109 comprising a first face 113 and a second face 114, a first projection 103 coupled to the first face 113 of the tray base 109, and a second projection 104 coupled to the first face 113. In some embodiments, the tray 102 may be coupled to the chassis 101 by a hinge 105. The hinge 105 may be coupled to both the tray 102 and the first side portion 106 as illustrated. In some embodiments, a printed circuit board (not shown) may be coupled to the chassis 101 and a second printed circuit board (not shown) may be coupled to the second face 114 of the tray 102 and a third printed circuit board (not shown) may be coupled to the first face 113 of the tray 102.

The first projection 103 may be substantially perpendicular to the first face of the tray base 109 and the second projection may be substantially perpendicular to the first face of the tray base 109. The first projection 103 may comprise a first end coupled to the tray base 109 and a detached second end. The second projection 104 may comprise a third end coupled to the tray base 109 and a detached fourth end. In some embodiments, the first projection may comprise a first portion 115, a second portion 116, and a third portion 117. The first portion 115 may be coupled to the tray 102 and perpendicular to the tray 102. The second portion 116 may be coupled to the first portion 115 and parallel to the tray. The third portion 117 may be coupled to the second portion 116, perpendicular to the second portion 116, and parallel to the first portion 115.

The hinge 105 may comprise a first hinge sleeve 120, a second hinge sleeve 119, and a double hinge sleeve insert 118. The first hinge sleeve 120 may be coupled to the first side portion 106 of the chassis 101. The second hinge sleeve 119 may be coupled to the tray 102. In some embodiments the double hinge sleeve insert 118 may be coupled to the first hinge sleeve 120 via a first pin (not shown) and coupled to the second hinge sleeve 119 via a second pin (not shown).

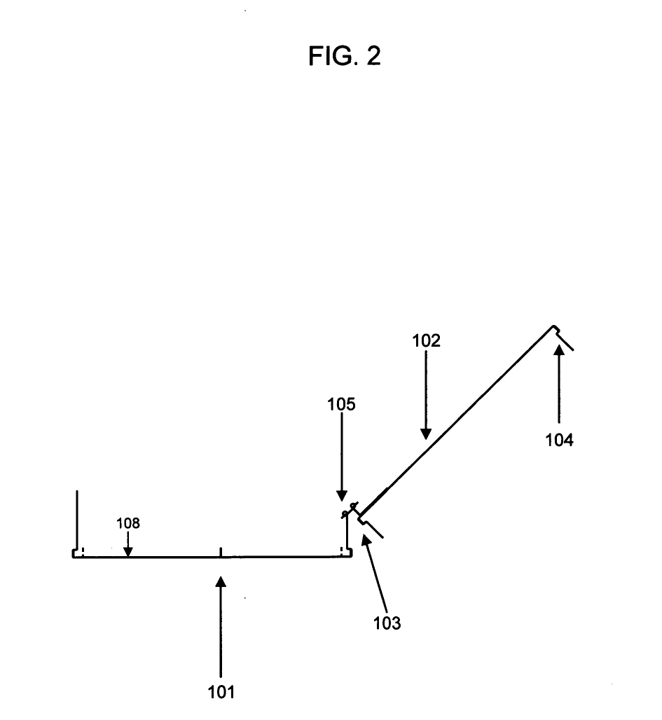

As illustrated in FIG. 2, the tray 102 may be uncoupled from the second side portion 107 and may rotate away from chassis 101. In some embodiments this rotation is facilitated by hinge 105.

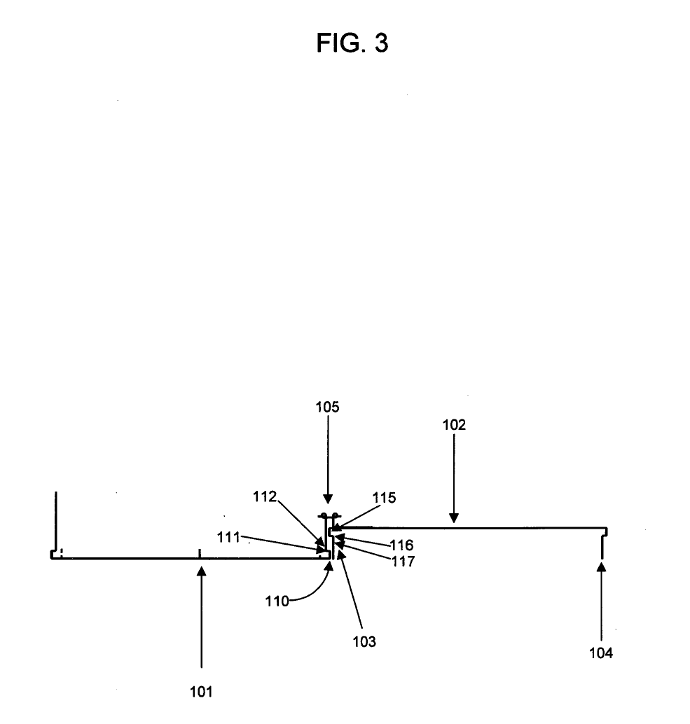

Next, as illustrated in FIG. 3, the rotation may continue until the second end of the first projection 103 and the fourth end of the second projection 104 are substantially coplanar with the chassis base 108.

In particular, the first projection 103 may be coupled to the first side portion 106 at substantially 180 degrees of rotation and, in some embodiments, the first portion 115 and the third portion 117 of the first projection 103 may be coupled to the third part 112 and the first part 110 of the first side portion 106 respectively. In some embodiments, at substantially 180 degrees of rotation, the hinge 105 may be parallel with the chassis base 108. In some embodiments, the hinge 105 may create a gap or space between the chassis 101 and the tray 102 to provide clearance for the first side portion 106 and the first projection 103. Limiting the rotation of the tray 102 to 180 degrees may improve serviceability of the chassis 101 and tray 102 over conventional means.

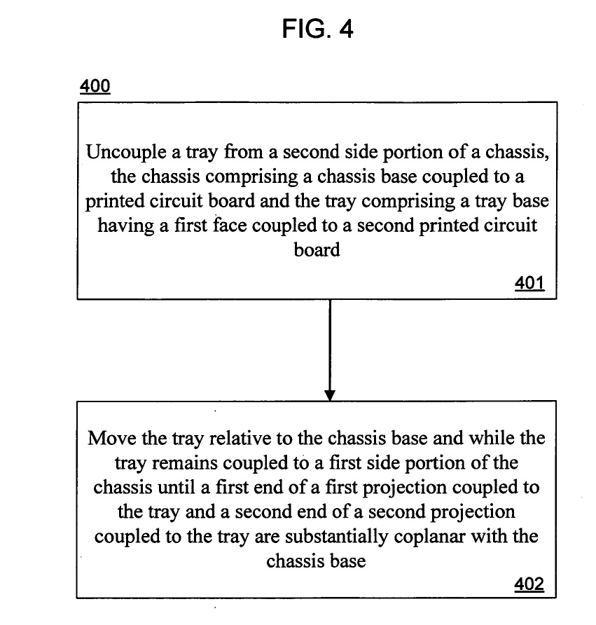

FIG. 4 illustrates an embodiment of a method 400 that may be implemented by, but is not limited to, the apparatus of FIG. 1. At 401, a tray is uncoupled from a second side portion of a chassis, where the chassis comprises a chassis base coupled to a printed circuit board and the tray comprising a tray base having a first face coupled to a second printed circuit board. For example, and in reference to FIG. 1, the tray 101 may be uncoupled from the second side portion 107 of chassis 101 by rotating the base 102 via hinge 105 coupled to the first side portion 106.

Next, the tray is moved relative to the chassis base and while the tray remains coupled to a first side portion of the chassis. The tray is moved until a first end of a first projection coupled to the tray and a second end of a second projection coupled to the tray are substantially coplanar with the chassis base.

According to some embodiments of 402, the second end of the first projection 103 and the fourth end of the second projection 104 may be substantially coplanar with the chassis base 108 after the tray 102 is rotated 180 degrees.

In some embodiments, the method 400 may further comprise coupling a module to a printed circuit board coupled to a second face of the tray base. In some embodiments, the method 400 also or alternatively comprises uncoupling a module from the printed circuit board.

In some embodiments, the method 400 may further comprise moving the tray until closed. Moving the tray until closed may comprise rotating the tray in an opposite direction relative to the chassis base such that a double hinge sleeve insert coupled to a first hinge sleeve via a first pin and coupled to a second hinge sleeve via the second pin is substantially coplanar with a second side portion of the chassis and the tray is again coupled to the second side portion of the chassis.

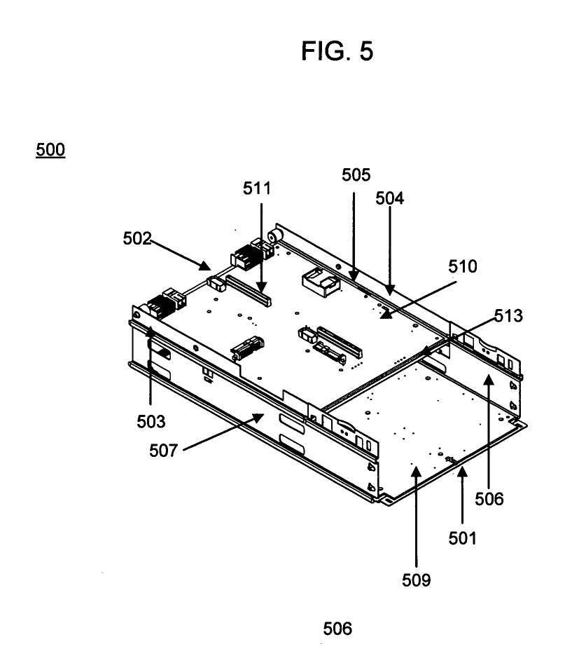

Now referring to FIG. 5, an embodiment of a system 500 is shown. The system 500 may comprise a chassis 501 coupled to a tray 502. The chassis 501 comprises a first side portion 506, and a second side portion 507, and the tray 502 comprises a first projection 503 and a second projection 504. In some embodiments, the chassis 501, the tray 502, the first side portion 506, the second side portion 507, the first projection 503, and the second projection 504 may be arranged similarly to the respectively named elements of FIG. 1.

In some embodiments, the tray 502 may be coupled to the chassis 501 by a hinge 505. The chassis 501 may be coupled to a printed circuit board 509. In some embodiments, the printed circuit board 509 may be a motherboard. A printed circuit board 510 may be coupled to a first face 513 of the tray 502 and a plurality of modules 511 may be coupled to the printed circuit board 510. In some embodiments, the modules 511 may be, but are not limited to, memory modules, processors, connectors, and sockets.

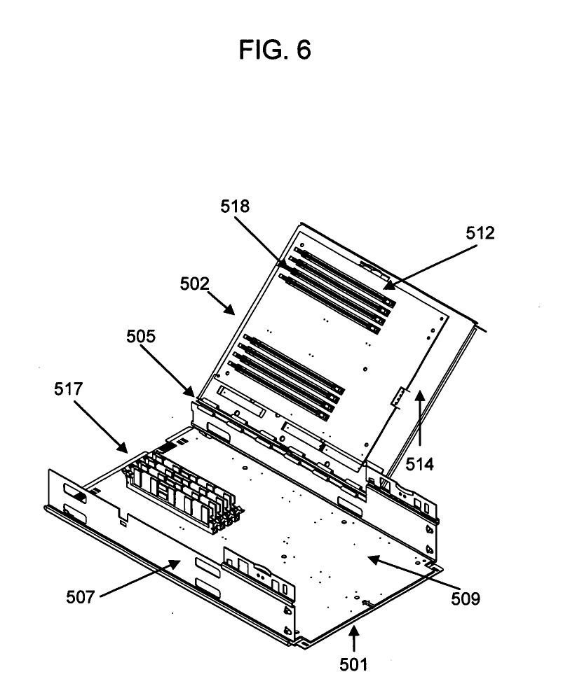

As illustrated in FIG. 6, the tray 502 may be uncoupled from the second side portion 507 and may rotate away from chassis 501. In some embodiments this rotation is facilitated by hinge 505.

In some embodiments, the printed circuit board 509 may be coupled to a plurality of modules 517. As illustrated in FIG. 6, the modules 517 may comprise a plurality of memory modules and a plurality of memory sockets.

A second face 514 of the tray 502 may be coupled to a printed circuit board 512. In some embodiments, the printed circuit board 512 may comprise a plurality of modules 518 coupled to the printed circuit board 512. As illustrated, the modules 518 may comprise a plurality of memory modules, a plurality of memory sockets, and a plurality of other electrical components.

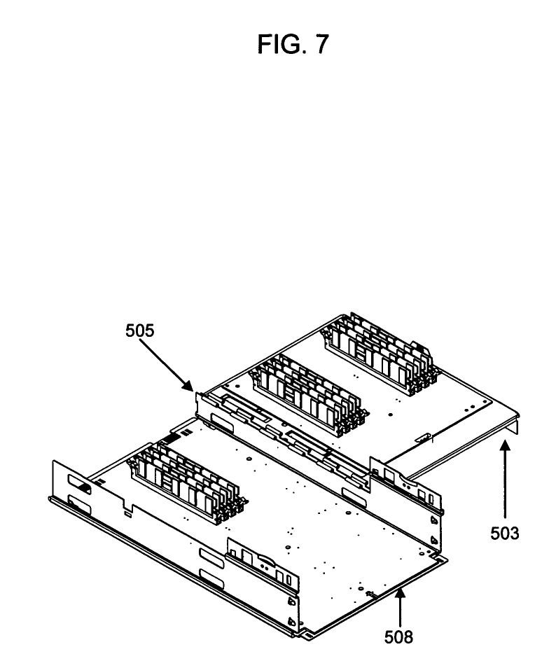

Next, as illustrated in FIG. 7, the rotation may continue until a second end of the first projection 503 and a detached end of a second projection (not shown) are substantially coplanar with the chassis base 508. In some embodiments, at substantially 180 degrees of rotation, the hinge 505 may be parallel with the chassis base 508.

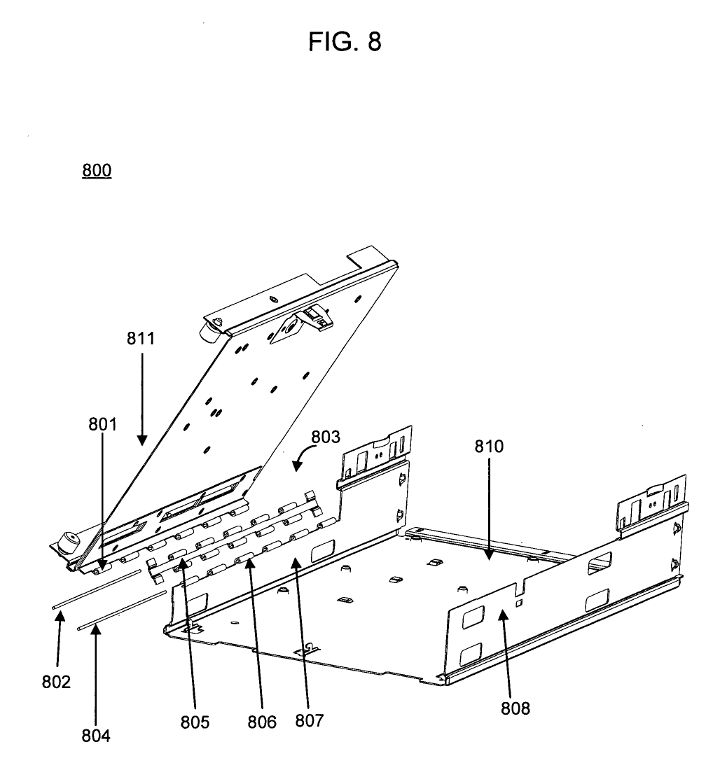

Now referring to FIG. 8, an embodiment of a system 800 is shown. The system 800 may comprise a chassis 810 coupled to a tray 811, where the chassis 808 comprises a first side portion 807 and a second side portion 808. The chassis 810 may be coupled to the tray 811 by a hinge 803. The hinge 803 may comprise a first hinge sleeve 806, a second hinge sleeve 801, a double hinge sleeve insert 805, a first pin 804, and a second pin 802. The first hinge sleeve 806 may be coupled to the first side portion 807 and the second hinge sleeve 801 may be coupled to the tray 811. The double hinge sleeve insert 805 may be coupled to the first hinge sleeve 806 via the first pin 804 and the second hinge sleeve 801 may be coupled to the double hinge sleeve insert 805 by the second pin 802.

The foregoing disclosure has been described with reference to specific exemplary embodiments thereof. It will, however, be evident that various modifications and changes may be made thereto without departing from the broader spirit and scope set forth in the appended claims.

What is claimed is:

1. An apparatus comprising:
a printed circuit board;
a second printed circuit board;
a chassis coupled to the printed circuit board and comprising a chassis base, a first side portion, and a second side portion; and
a tray coupled to the chassis and comprising a tray base having a first face and a second face, a first projection substantially perpendicular to the first face, and a second projection substantially perpendicular to the first face,
wherein the second printed circuit board is coupled to the second face of the tray base.

2. The apparatus of claim 1, wherein the first projection comprises a first end coupled to the tray base and a detached second end, and
wherein the second projection comprises a third end coupled to the tray base and a detached fourth end.

3. The apparatus of claim 1, wherein the tray is to rotate until the second end of the first projection and the fourth end of the second projection are substantially coplanar with the chassis base.

4. The apparatus of claim 1, wherein the tray is coupled to the chassis via a hinge.

5. The apparatus of claim 4, wherein the hinge comprises:
a first pin;
a second pin;
a first hinge sleeve coupled to the first side portion of the chassis;
a second hinge sleeve coupled to the tray; and
a double hinge sleeve insert coupled to the first hinge sleeve via the first pin and coupled to the second hinge sleeve via the second pin.

6. The apparatus of claim 1, wherein the first projection is to limit rotation of the tray to 180 degrees.

7. The apparatus of claim 1, wherein the first projection comprises:
a first portion coupled to the tray and perpendicular to the tray;
a second portion coupled to the first portion and parallel to the tray; and
a third portion coupled to the second portion, perpendicular to the second portion, and parallel to the first portion.

8. A method comprising:
uncoupling a tray from a second side portion of a chassis, the chassis comprising a chassis base coupled to a printed circuit board and the tray comprising a tray base having a first face coupled to a second printed circuit board;
moving the tray relative to the chassis base and while the tray remains coupled to a first side portion of the chassis until a first end of a first projection coupled to the tray and a second end of a second projection coupled to the tray are substantially coplanar with the chassis base.

9. The method of claim 8, further comprising coupling a module to the second printed circuit board, and wherein the first projection and the second projection are coupled to a second face of the tray base.

10. The method of claim 9, further comprising uncoupling a second module from the second printed circuit board.

11. The method of claim 9, further comprising moving the tray until closed, wherein moving the tray until closed comprises rotating the tray relative to the chassis base such that a double hinge sleeve insert coupled to a first hinge sleeve via a first pin and coupled to a second hinge sleeve via the second pin is substantially coplanar with a second side portion of the chassis and the tray is coupled to the second side portion of the chassis.

12. A system comprising:
a motherboard;
a second printed circuit board;
a processor coupled to the motherboard;
a double data rate memory module coupled to the second printed circuit board;
a chassis coupled to the motherboard and comprising a chassis base, a first side portion, and a second side portion; and
a tray coupled to the chassis and comprising a tray base having a first face and a second face, a first projection substantially perpendicular to the first face, and a second projection substantially perpendicular to the first face,
wherein the second printed circuit board is coupled to the second face of the tray base.

13. The system of claim 12, wherein the first projection comprises a first end coupled to the tray base and a detached second end, and
wherein the second projection comprises a third end coupled to the tray base and a detached fourth end.

14. The system of claim 12, wherein the tray is to rotate until the second end of the first projection and the fourth end of the second projection are substantially coplanar with the chassis base.

15. The system of claim 12, wherein the tray is coupled to the chassis via a hinge.

16. The system of claim 15, wherein the hinge comprises:
a first pin;
a second pin;
a first hinge sleeve coupled to the first side portion of the chassis;
a second hinge sleeve coupled to the tray; and
a double hinge sleeve insert coupled to the first hinge sleeve via the first pin and coupled to the second hinge sleeve via the second pin;

17. The system of claim 12, wherein the first projection is to limit rotation of the tray to 180 degrees.

18. The system of claim 12, wherein the first projection comprises:
a first portion coupled to the tray and perpendicular to the tray;
a second portion coupled to the first portion and perpendicular to the tray; and
a third portion coupled to the second portion, perpendicular to the second portion and parallel to the first portion.
